(19) United States
(12) Patent Application Publication
(10) Pub. No.: US 2012/0298169 A1
(43) Pub. Date: Nov. 29, 2012

(54) Multi-junction Photovoltaic Cells

(76) Inventors: George X. Guo, Palo Alto, CA (US); Zhengyu Zhang, Beijing (CN)

(21) Appl. No.: 13/299,535

(22) Filed: Nov. 18, 2011

Related U.S. Application Data
(60) Provisional application No. 61/490,165, filed on May 26, 2011.

(51) Int. Cl. H01L 31/05; H01L 31/0296; H01L 31/06

(52) U.S. Cl. 136/244; 136/255; 438/94; 438/95; 257/E31.016

(57) ABSTRACT

A multi junction photovoltaic device includes lower pn junction layers comprising silicon and upper pn junction layers formed over the lower pn junction layers. The upper pn junction layers include a CdTe layer, wherein the upper pn junction layers are electrically serially connected to the lower pn junction layers. The upper pn junction layers can convert a first portion of photons into a first electric voltage. The lower pn junction layers can convert a second portion of photons into a second electric voltage lower than the first electric voltage.

The present application claims priority to pending U.S. Provisional Patent Application 61/490,165, entitled “Process and apparatus for incorporating CdTe photovoltaic cell on top of silicon photovoltaic devices”, filed by the same inventors on May 26, 2011, the disclosures of which is incorporated herein by reference.

### BACKGROUND OF THE INVENTION

The present application relates to the fabrication of photovoltaic solar cells.

Although photovoltaic solar cells can be fabricated by a number of different materials and configurations, the photovoltaic market is dominated by silicon-based photovoltaic solar cells. The efficiency of silicon-based photovoltaic solar cells is close to its theoretical limit.

A cross-section of a silicon-based photovoltaic cell 100 is shown in FIG. 1, which includes, from the bottom to the top, a backside screen printed contact layer 110, Si pn junction layers 120, a SiN passivation layer 130, and screen printed silver strips 140.

One drawback of the silicon photovoltaic cells is that the single bandgap structure with a relatively low band gap (˜1.1 eV) and result in a low voltage (around 0.6 to 0.7 volts from a single cell. Many silicon photovoltaic cells need to be serially connected to provide adequate voltage for transmission and usage. Another drawback of the silicon photovoltaic cells is that its single junction structure limits the maximum efficiency that can be achieved.

There is therefore a need to provide efficiency and high voltage in photovoltaic cells to satisfy the increased demand and wider range of application of the photovoltaic cell market.

### SUMMARY OF THE INVENTION

The presently disclosed devices provide higher voltage and higher light conversion efficiency compared to conventional silicon photovoltaic cells. The present invention discloses a multi junction photovoltaic device to increase the solar cell efficiency. The multi-junction photovoltaic device includes two stacked solar cells having different band gap energies. A top solar cell captures the shorter wavelength photons and allows the longer wavelength photons to pass through. A lower solar cell can capture the longer wavelength photons and convert them into electric current. The voltage on the top solar cell is higher than the bottom solar cell due to the higher band gap. The total voltage of the tandem photovoltaic device is much higher than the voltage of a conventional silicon photovoltaic cell. The disclosed device has higher total efficiency because it can convert photons in a wider spectral range into electricity and minimize the voltage loss for a single junction solar cell.

In one general aspect, the present invention relates to a multi junction photovoltaic device that includes lower pn junction layers comprising silicon; and upper pn junction layers formed over the lower pn junction layers, wherein the upper pn junction layers can include a CdTe layer, wherein the upper pn junction layers are electrically serially connected to the lower pn junction layers, wherein the upper pn junction layers can convert a first portion of photons into a first electric voltage, and wherein the lower pn junction layers can convert a second portion of photons into a second electric voltage lower than the first electric voltage.

Implementations of the system may include one or more of the following. The multi-junction photovoltaic device can further include a first transparent conductive layer formed on the upper pn junction layers. The multi junction photovoltaic device can further include a second transparent conductive layer between the lower pn junction layers and the upper pn junction layers. The multi junction photovoltaic device can further include a patterned conduction layer on the first transparent conductive layer. At least some of the second portion of photons have longer wavelengths than the first portion of photons. The upper pn junction layers can include a semiconductor layer in contact with the CdTe layer. The semiconductor layer can include CdS or ZnS. The semiconductor layer can be formed on the CdTe layer in the upper pn junction layers. The CdTe layer can be formed on the semiconductor layer in the upper pn junction layers. The multi junction photovoltaic device can further include a back contact layer below the lower pn junction layers. The CdTe layer can be doped with Cu, Cl, or extra Cd. The lower pn junction layers and the upper pn junction layers together can produce a photoelectric voltage above 1.2 volt.

In another general aspect, the present invention relates to a photovoltaic module that includes a plurality of electrically serially connected multi junction photovoltaic devices. At least one of the multi junction photovoltaic devices includes lower pn junction layers comprising silicon; and upper pn junction layers formed over the lower pn junction layers. The upper pn junction layers can include a CdTe layer, wherein the upper pn junction layers are electrically serially connected to the lower pn junction layers. The upper pn junction layers can convert a first portion of photons into a first electric voltage. The lower pn junction layers can convert a second portion of photons into a second electric voltage lower than the first electric voltage.

In another general aspect, the present invention relates to a method for forming a multi junction photovoltaic device. The method includes forming lower pn junction layers comprising silicon; and forming upper pn junction layers formed over the lower pn junction layers. The upper pn junction layers can include CdTe layer. The upper pn junction layers are electrically serially connected to the lower pn junction layers. The upper pn junction layers can convert a first portion of photons into a first electric voltage. The lower pn junction layers can convert a second portion of photons into a second electric voltage lower than the first electric voltage.

The details of one or more embodiments are set forth in the accompanying drawings and in the description below. Other features, objects, and advantages of the invention will become apparent from the description and drawings, and from the claims.

### BRIEF DESCRIPTION OF THE DRAWINGS

FIG. 1 shows a cross-section of a conventional silicon-based photovoltaic cell.

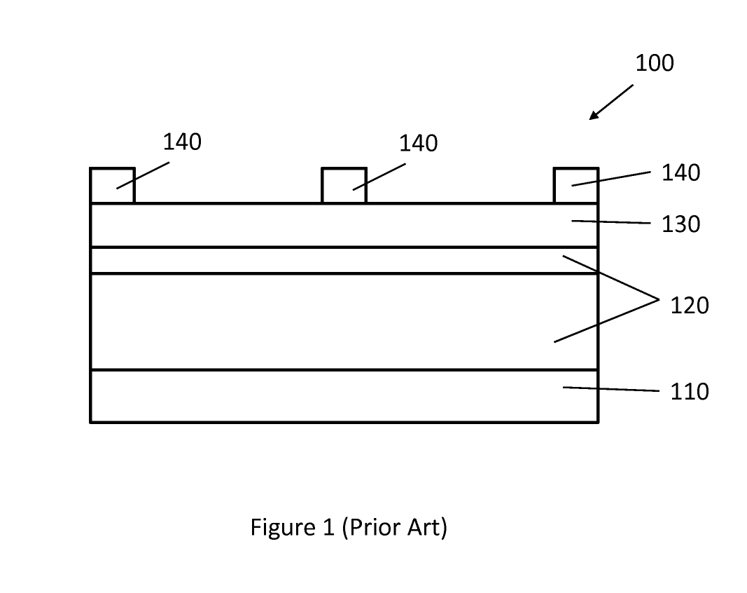

FIG. 2 is a cross sectional view of pn junction layers formed on in a silicon substrate.

FIG. 3 is a cross sectional view showing a back contact formed on the bottom surface of the silicon based pn junction layers.

FIG. 4 is a cross sectional view showing an optional transparent conductive layer formed on the silicon based pn junction layers.

FIG. 5 is a cross sectional view showing a CdTe layer formed on the optional transparent conductive layer or directly on the silicon based pn junction layers.

FIG. 6 is a cross sectional view showing a semiconductor layer formed on the CdTe layer forming a second pn junction.

FIG. 7 is a cross sectional view showing a CdTe layer formed on a semiconductor layer that is in turn formed on the optional transparent conductive layer or directly on the silicon based pn junction layers.

FIG. 8 is a cross sectional view showing a transparent conductive layer on the top pn junction layers.

FIG. 9 is a cross sectional view of a multi junction photovoltaic cell.

FIG. 10 is a cross sectional view of a multi junction photovoltaic module consisting of electrically serially connected multi junction photovoltaic cells.

### DETAILED DESCRIPTION OF THE INVENTION

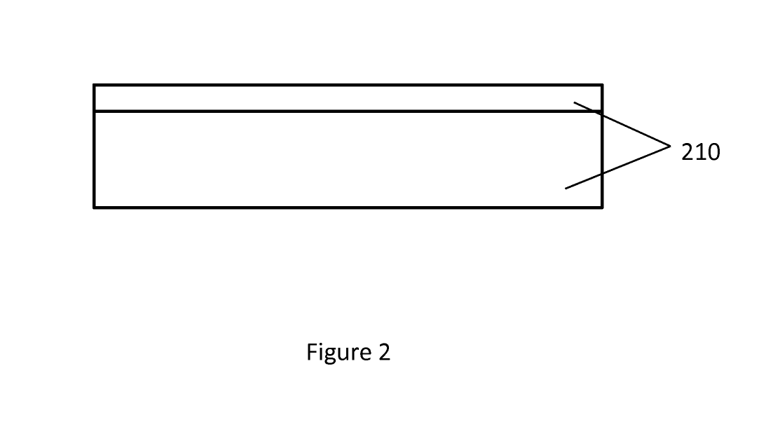

The present invention discloses a tandem photovoltaic device to increase the solar cell efficiency. Referring FIG. 2, pn junction layers 210 is formed on in a silicon substrate. The silicon based pn junction layers 210 can be formed by doping the layers respectively by n-type and p-type dopants, as known in the art. The top surface is not covered by screen printing.

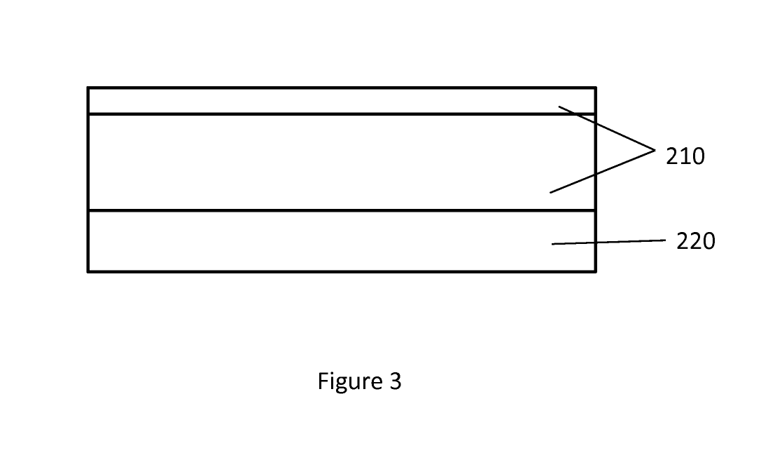

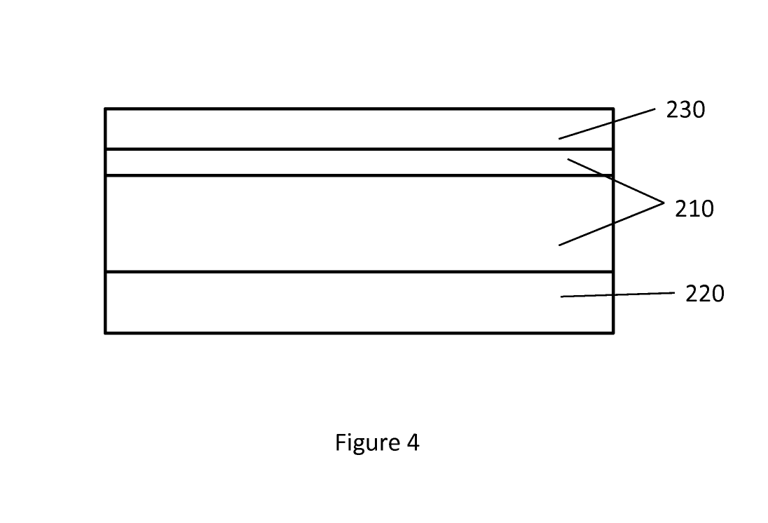

A back contact 220 can be formed on the lower surface of the pn junction layers 210, as shown in FIG. 3. The back contact 220 can also be formed at a later step. An optional transparent conductive layer 230, as shown in FIG. 4, is deposited on the silicon based pn junction layers 210 to enhance the collection of electrons. The transparent conductive layer 230 can for example be formed by transparent conductive oxide (TCO).

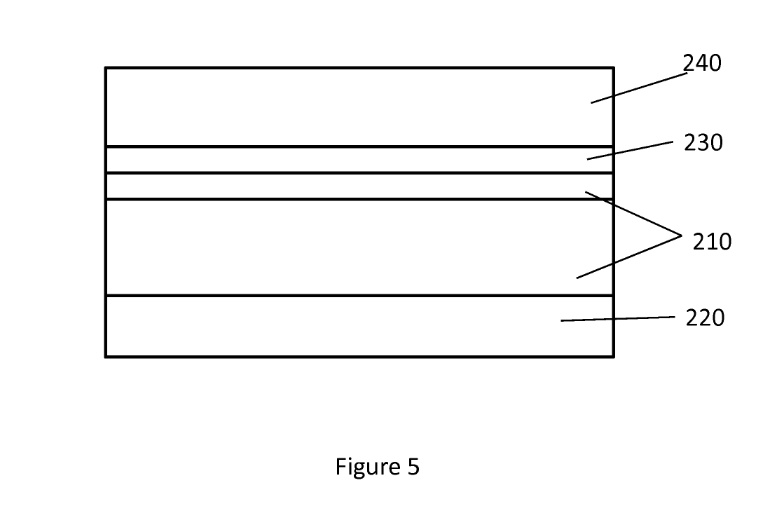

Next, a CdTe layer 240 is deposited directly on the silicon pn junction layers 210 or on the transparent conductor layer 230, as shown in FIG. 5. The CdTe layer 240 can be doped with Cu, Cl, and extra Cd to enhance the electrical contact with the layer below, the silicon pn junction layers 210 or the transparent conductor layer 230. The CdTe layer 240 can be deposited using evaporation, electro-plating, or sputtering method.

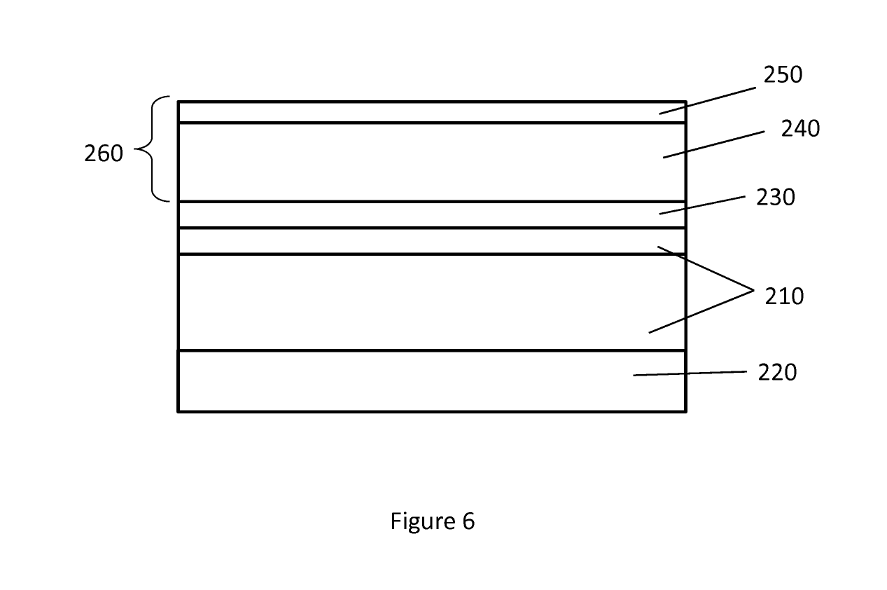

Next, referring to FIG. 6, a semiconductor layer 250 comprising a material such as CdS or ZnS is deposited to the CdTe layer 240 to form a second pn junction 260 with the CdTe layer 240. The pn junction 260 is electrically serially connected to the silicon based pn junction layers 210 below via the transparent conductor layer 230.

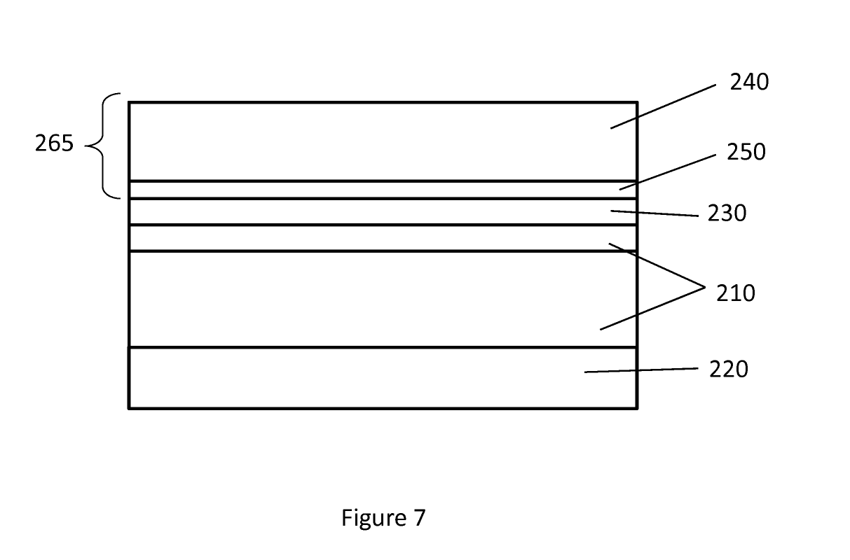

In some embodiments, referring to FIG. 7, the sequence of the CdTe layer 240 and the CdS layer 250 can be reversed: the semiconductor layer 250 on directly on the silicon pn junction layers 210 or on the transparent conductor layer 230. The CdTe layer 240 is formed on the semiconductor layer 250. Optional treatment processes such as CdCl₂ treatment can be carried out to enhance the properties of the CdTe device.

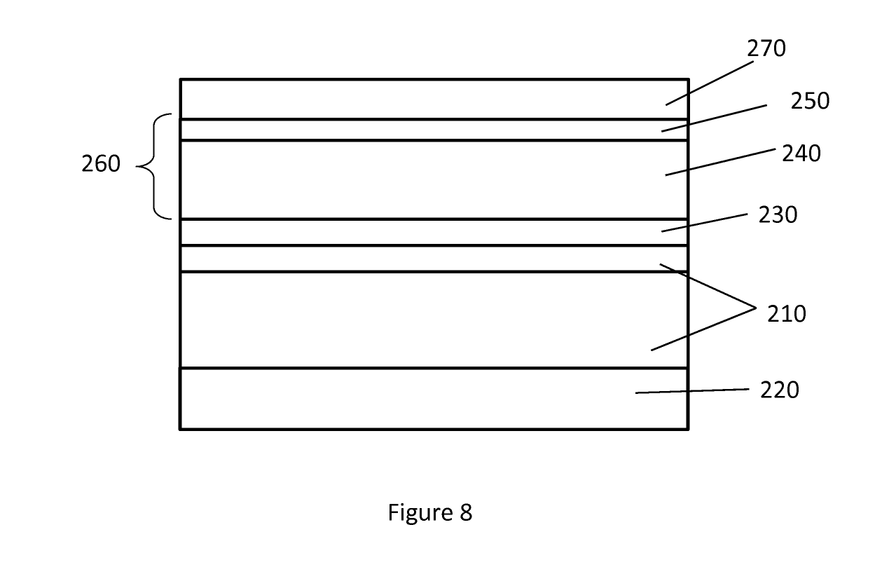

A transparent conductive layer 270, shown in FIG. 8, is formed on the pn junction layers 260 comprising the semiconductor layer 250 and the CdTe layer 240 (or on the pn junction layers 265 comprising the CdTe layer 240 on the semiconductor layer 250). The transparent conductive layer 270 can be made of an oxide material such as TCO.

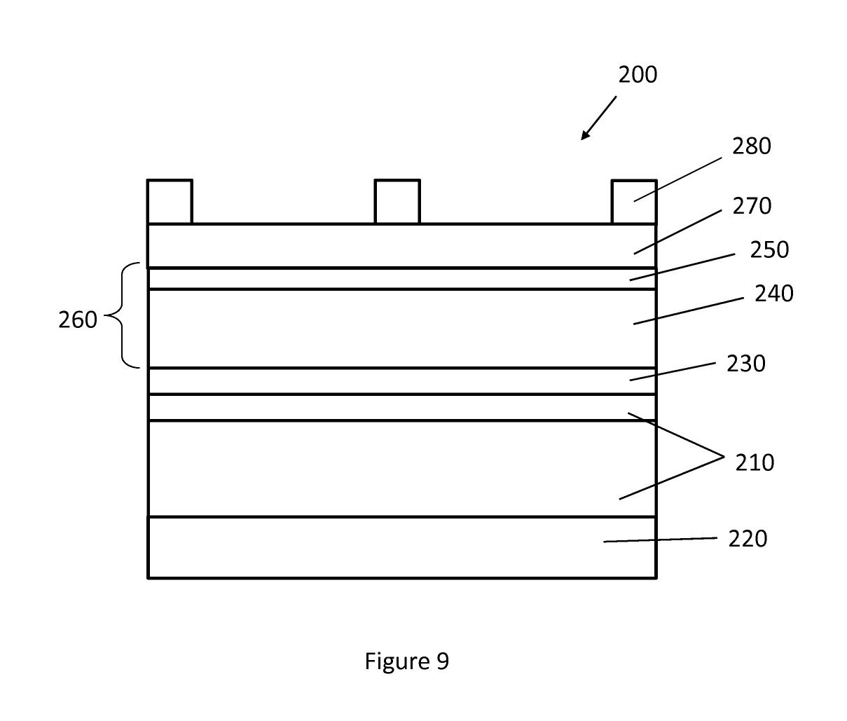

A (typically opaque) conductive layer 280 is next formed in a grid pattern on the transparent conductive layer 270, as shown in FIG. 9, which forms a multi junction photovoltaic device 200 in accordance with the present invention. The conductive layer 280 can be formed by screen printing and ink jet printing. As mentioned above, the back contact 220 can also be applied at this step at the bottom of the Si based pn junction layers 210.

The multi junction photovoltaic device 200 includes a CdTe based pn junction 260 (or 265) at the top, and a silicon based pn junction 210 in the bottom. Since CdTe has a band gap about 1.45 eV and crystalline silicon has a band gap around 1.1 eV, shorter wavelength photons can be captured and converted to electrons by the CdTe based pn junction 260 (or 265) at the top. Longer wavelength photons and unabsorbed short-wavelength photons can pass through the CdTe based pn junction 260 (or 265) and the transparent conductor layer 230, and then be captured and converted to electrons by the silicon based pn junction layers 210 in the bottom. The upper pn junction 260 or 265 produces a large photoelectric voltage than the lower pn junction 210.

The combination of large and small band gaps in the two pn junctions can capture photons in a wider spectral range and increase photon capture efficiency in comparison with conventional photovoltaic cells.

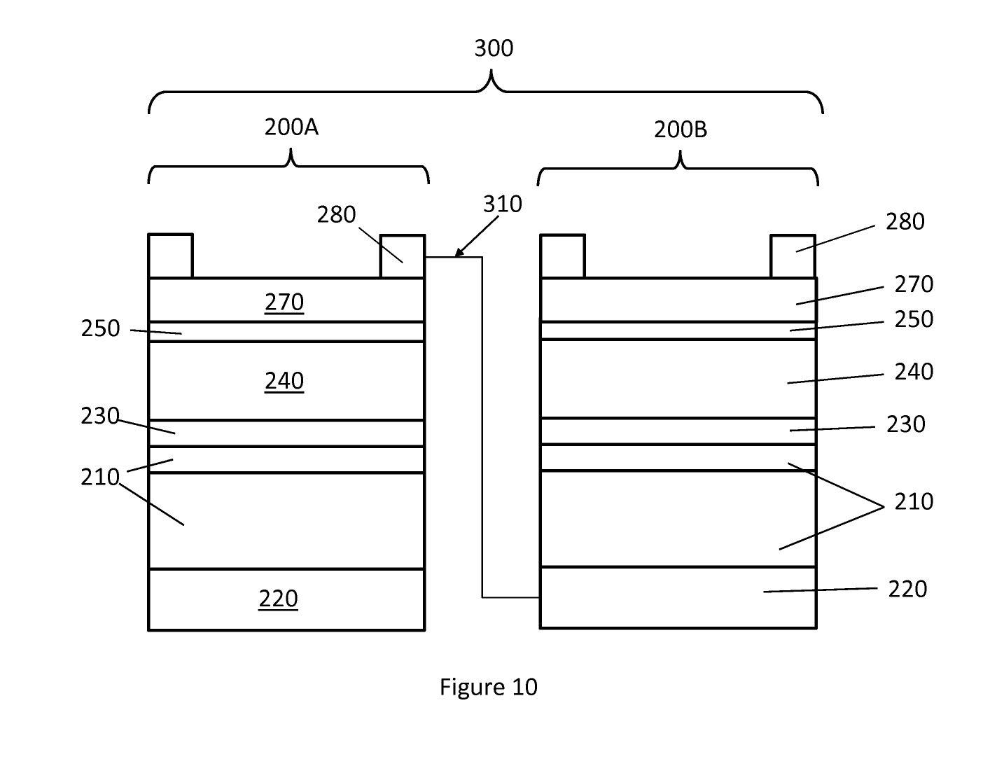

Furthermore, the multi junction photovoltaic device 200 can produce a high voltage output above 1.2 volt, which is much higher than the output voltage of conventional silicon-based single photovoltaic solar cell. Referring to FIG. 10, multi junction photovoltaic devices 200A and 200B made by the above described process can be electrically serially connected to form a multi junction photovoltaic module 300. The conductive layer 280 of the multi junction photovoltaic device 200A can be connected to the back contact 220 of the next multi junction photovoltaic device 200B with a conductive wire 310.

Because a unit multi junction photovoltaic device produces a high voltage output, it takes much fewer serially connected multi junction photovoltaic devices in a photovoltaic module to provide a required output voltage.

An additional advantage of the presently disclosed photovoltaic cells is that the higher energy photons are converted into energy in the top photovoltaic cells for the short wave length photons. More electric energy can be produced from the same amount of photons, In other words, the output power per unit area is increased compared to conventional silicon based photo voltaic devices.

It is understood that the disclosed systems are compatible with many different types of processing operations such as physical vapor deposition (PVD), thermal evaporation, thermal sublimation, sputtering, CVD, PECVD, ion etching, or sputter etching.

What is claimed is:

1. A multi junction photovoltaic device, comprising:
lower pn junction layers comprising silicon; and
upper pn junction layers formed over the lower pn junction layers, wherein the upper pn junction layers comprise a CdTe layer, wherein the upper pn junction layers are electrically serially connected to the lower pn junction layers, wherein the upper pn junction layers are configured to convert a first portion of photons into a first electric voltage, and wherein the lower pn junction layers are configured to convert a second portion of photons into a second electric voltage lower than the first electric voltage.

2. The multi junction photovoltaic device of claim 1, further comprising:
a first transparent conductive layer formed on the upper pn junction layers.

3. The multi junction photovoltaic device of claim 2, further comprising:
a second transparent conductive layer between the lower pn junction layers and the upper pn junction layers.

4. The multi junction photovoltaic device of claim 2, further comprising:
a patterned conduction layer on the first transparent conductive layer.

5. The multi junction photovoltaic device of claim 1, wherein at least some of the second portion of photons have longer wavelengths than the first portion of photons.

6. The multi junction photovoltaic device of claim 1, wherein the upper pn junction layers comprise a semiconductor layer in contact with the CdTe layer, wherein the semiconductor layer comprises CdS or ZnS.

7. The multi junction photovoltaic device of claim 6, wherein the semiconductor layer is formed on the CdTe layer in the upper pn junction layers.

8. The multi junction photovoltaic device of claim 6, wherein the CdTe layer is formed on the semiconductor layer in the upper pn junction layers.

9. The multi junction photovoltaic device of claim 1, further comprising:
a back contact layer below the lower pn junction layers.

10. The multi junction photovoltaic device of claim 1, wherein the CdTe layer is doped with Cu, Cl, or extra Cd.

11. The multi junction photovoltaic device of claim 1, wherein the lower pn junction layers and the upper pn junction layers together are configured to produce a photoelectric voltage above 1.2 volt.

12. A photovoltaic module, comprising:
a plurality of electrically serially connected multi junction photovoltaic devices, wherein at least one of the multi junction photovoltaic devices comprises:
lower pn junction layers comprising silicon; and
upper pn junction layers formed over the lower pn junction layers, wherein the upper pn junction layers comprise a CdTe layer, wherein the upper pn junction layers are electrically serially connected to the lower pn junction layers, wherein the upper pn junction layers are configured to convert a first portion of photons into a first electric voltage, and wherein the lower pn junction layers are configured to convert a second portion of photons into a second electric voltage lower than the first electric voltage.

13. The photovoltaic module of claim 12, wherein the at least one of the multi junction photovoltaic devices further comprises:
a first transparent conductive layer formed on the upper pn junction layers; and
a back contact layer below the lower pn junction layers, wherein at least one of the first transparent conductive layer or the back contact layer is electrically connected to another one of the multi junction photovoltaic devices.

14. The photovoltaic module of claim 12, wherein the upper pn junction layers comprise a semiconductor layer in contact with the CdTe layer, wherein the semiconductor layer comprises CdS or ZnS.

15. The photovoltaic module of claim 13, wherein at least some of the second portion of photons have longer wavelengths than the first portion of photons.

16. A method for forming a multi junction photovoltaic device, comprising:
forming lower pn junction layers comprising silicon; and
forming upper pn junction layers formed over the lower pn junction layers, wherein the upper pn junction layers comprise a CdTe layer, wherein the upper pn junction layers are electrically serially connected to the lower pn junction layers, wherein the upper pn junction layers are configured to convert a first portion of photons into a first electric voltage, and wherein the lower pn junction layers are configured to convert a second portion of photons into a second electric voltage lower than the first electric voltage.

17. The method of claim 16, further comprising:
forming a first transparent conductive layer on the upper pn junction layers; and
forming a back contact layer below the lower pn junction layers.

18. The method of claim 16, further comprising:
forming the CdTe layer by evaporation, electro-plating, or sputtering.

19. The method of claim 16, further comprising:
doping the CdTe layer with Cu, Cl, or extra Cd.

20. The method of claim 16, further comprising:
forming a first transparent conductive layer on the upper pn junction layers; and
forming a patterned conduction layer on the first transparent conductive layer by screen printing or inkjet printing.
